(19) United States
(12) Patent Application Publication
(10) Pub. No.: US 2009/0243025 A1
(43) Pub. Date: Oct. 1, 2009

(54) PIXEL STRUCTURE WITH A PHOTODETECTOR HAVING AN EXTENDED DEPLETION DEPTH

(76) Inventors: Eric G. Stevens, Webster, NY (US); Hung Q. Doan, Rochester, NY (US); Shou-Gwo Wuu, Hsin-Chu City (TW); Chung-Wei Chang, Hsinchu (TW)

Correspondence Address: F-P, Patent Legal Staff;Eastman Kodak Company, 343 State Street, Rochester, NY, 14650-2201, US

(21) Appl. No.: 12/054,505

(22) Filed: Mar. 25, 2008

(51) Int. Cl. H01L 31/101

(52) U.S. Cl. 257/461; 257/E31.054

(57) ABSTRACT

An image sensor includes an imaging area that includes a plurality of pixels that are formed in a substrate layer of a first conductivity type. Each pixel includes a collection region that is formed in a portion of the substrate layer and doped with a dopant of a first conductivity type. A plurality of wells are disposed in portions of the substrate layer and doped with another dopant of the second conductivity type. Each well is positioned laterally adjacent to each collection region. A buried layer spans the imaging area and is disposed in a portion of the substrate layer that is beneath the photodetectors and the wells. The buried layer is doped with a dopant of a second conductivity type. Each collection region, each well, and the buried layer are formed such that a region of the substrate layer having substantially the same doping as the substrate layer resides between each collection region and the buried layer.

### TECHNICAL FIELD

The invention relates generally to the field of image sensors, and in particular to image sensors that include a photodetector structure with an extended depletion depth.

### BACKGROUND

It is becoming more difficult to maintain some key performance aspects of an image sensor as the demand for higher resolutions within a given optical format continues to increase and pixel size continues to decrease. In particular, as pixel sizes become smaller, the quantum efficiency of a pixel degrades and crosstalk between pixels increases. One method to reduce pixel-to-pixel crosstalk combines a vertical overflow drain (VOD) structure with a pixel built into a well. This technique is described in an article entitled “A 3.25 M-pixel APS-C Size CMOS Image Sensor” by S. Inoue et al., Eisoseiho Media Gakkai Gijutsu Hokoku (Technology Report, Image Information Media Association) Eiseigakugiko, vol. 25, no. 28, pp. 37-41, March 2001. ISSN 1342-6893). Another method to reduce crosstalk uses a hole-based detector that is built in an n-well, where the n-well resides on a p-substrate. This technique is disclosed in United States Patent Publication 2007/0108371A1. Although these prior art methods reduce pixel-to-pixel crosstalk, quantum efficiency is sacrificed for light propagating at the longer wavelengths.

Increasing the depletion depth of a photodetector can improve quantum efficiency and reduces crosstalk because the collection efficiency of the device is increased. A recent example of a method to increase the depletion depth is disclosed in United States Patent Publication 2007/0069260A1. A series of extra implants are added in a photodiode to form a lightly doped tail that extends deeper into the silicon. Unfortunately, this technique adds extra processing steps to the manufacturing process. Another issue with this approach has to do with the alignment of these high-energy implants. Since the projected range of the higher energy implants is quite large, these implants can penetrate the transfer gate, and hence, are no longer self-aligned to the transfer gate edge. Therefore, if the alignment of these implants is not held very tight, the implants can penetrate the transfer gate and increase image lag. To avoid the lag issue, one approach reduces the dose of the photodiode's surface implant component, but this can result in a loss of charge capacity.

Therefore, there exists a need within the art to provide a pixel structure that improves quantum efficiency and reduces pixel-to-pixel crosstalk simultaneously, without adding extra processing steps to the fabrication process and without impacting other performance characteristics of the image sensor.

### SUMMARY

A pixel structure includes an imaging area having a plurality of pixels. Each pixel in the imaging area includes a substrate layer of a first conductivity type. The term “substrate layer” includes a substrate with an epitaxial layer formed thereon and a bulk wafer substrate without an epitaxial layer.

A buried layer that spans the imaging area and a well are formed in portions of the substrate layer and are each doped with a dopant of a second conductivity type. A collection region of a photodetector is formed laterally adjacent to the well and is doped with a dopant of the first conductivity type. Finally, an optional pinning layer is formed in a portion of the collection region and doped with a dopant of the second conductivity type. If a pinning layer is included in the pixel structure, the collection region and pinning layer form a pinned photodetector.

Both the collection region and the buried layer are formed in the substrate layer such that an undoped region of the substrate layer resides between the collection region and the buried layer. The region is called “undoped” because the doping of the undoped region is substantially the same as the doping of the substrate layer. This undoped region effectively produces an “extension” of the collection region of the photodetector. This extension results in a deeper depletion depth and a deeper junction depth for the photodetector.

These and other aspects, objects, features and advantages of the present invention will be more clearly understood and appreciated from a review of the following detailed description of the preferred embodiments and appended claims, and by reference to the accompanying drawings.

### Advantageous Effect Of The Invention

The present invention has the advantage of extending the depletion depth of a photodetector, which improves the collection efficiency of the photodetector. The present invention also reduces pixel-to-pixel crosstalk between adjacent pixels while maintaining other performance characteristics of an image sensor. And finally, the present invention does not add extra steps to the fabrication process for an image sensor.

### BRIEF DESCRIPTION OF THE DRAWINGS

FIG. 1 is a top view of a pixel commonly used in a CMOS image sensor in accordance with the prior art;

FIG. 2 is a cross-sectional schematic view along line A-A′ in FIG. 1 depicting a prior art pixel structure;

FIG. 3 is a graphical view of exemplary junction and depletion edges for collection region 206 shown in FIG. 2;

FIG. 4 is an exemplary one-dimensional potential profile of photodetector 100 taken along line B-B′ in FIG. 2;

FIG. 5 is a cross-sectional schematic view along line A-A′ in FIG. 1 illustrating a first pixel structure in an embodiment in accordance with the invention;

FIG. 6 is a cross sectional view along line A-A′ in FIG. 1 depicting a second pixel structure in an embodiment in accordance with the invention;

FIG. 7 illustrates an exemplary one-dimensional doping profile of photodetector 512 taken along line C-C′ in FIG. 5 and along line D-D′ in FIG. 6;

FIG. 8 is an exemplary one-dimensional potential profile of photodetector 512 taken along line C-C′ in FIG. 5 and along line D-D′ in FIG. 6;

FIG. 9 is an exemplary two-dimensional cross-sectional view showing the junctions and depletion boundaries of collection region 514 in FIG. 5;

FIG. 10 is a block diagram of a top view of an image sensor in an embodiment in accordance with the invention;

FIGS. 11(A)-11(E) are cross-sectional views of a portion of a pixel that are used to illustrate a method of fabricating buried layer 508, well 510, and photodetector 512 in an embodiment in accordance with the invention; and

FIG. 12 is a block diagram of an imaging system that can be used with an image sensor that incorporates the pixel structure with photodetectors having extended depletion depths in an embodiment in accordance with the invention.

### DETAILED DESCRIPTION

Throughout the specification and claims, the following terms take the meanings explicitly associated herein, unless the context clearly dictates otherwise. The meaning of “a,” “an,” and “the” includes plural reference, the meaning of “in” includes “in” and “on” The term “connected” means either a direct electrical connection between the items connected or an indirect connection through one or more passive or active intermediary devices. The term “circuit” means either a single component or a multiplicity of components, either active or passive, that are connected together to provide a desired function. The term “signal” means at least one current, voltage, or data signal. Referring to the drawings, like numbers indicate like parts throughout the views.

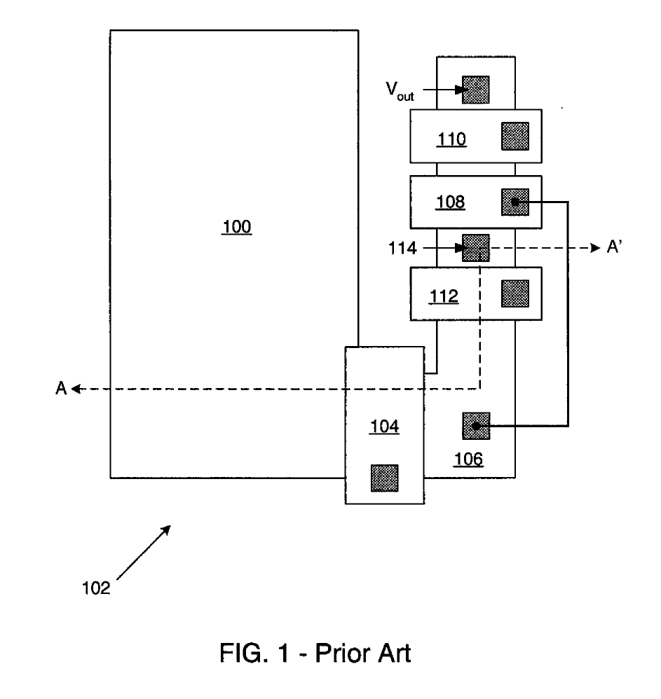

Referring now to FIG. 1, there is shown a top view of a pixel commonly used in a CMOS image sensor in accordance with the prior art. Although only one pixel is shown, those skilled in the art will recognize an image sensor includes a number of pixels that are typically arranged in rows and columns. For example, an image sensor can have many millions of pixels.

Pixel 102 includes photodetector 100 that generates and stores charge in response to light striking photodetector 100. Transfer gate 104 is used to transfer the integrated charge in photodetector 100 to charge-to-voltage converter 106. Converter 106 converts the charge into a voltage signal. Source-follower transistor 108 buffers the voltage signal stored in charge-to-voltage converter 106. Row select transistor 110 selectively connects the output (Vₒᵤₜ) to a column bus (not shown). Reset transistor 112 is used to reset converter 106 to a known potential prior to pixel readout. And power supply voltage (VSS) 114 is used to supply power to source follower transistor 108 and drain off signal charge from converter 106 during a reset operation.

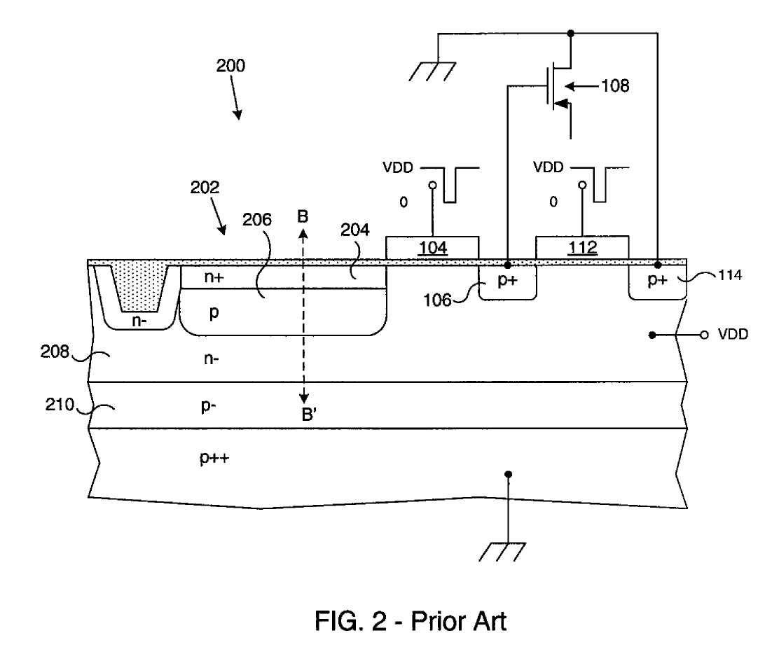

FIG. 2 is a cross-sectional schematic view along line A-A′ in FIG. 1. The pixel structure shown in FIG. 2 is disclosed in States Patent Publication 2007/0108371. Pixel 200 includes transfer gate 104, charge-to-voltage converter 106, source follower transistor 108, and reset gate 112 described in conjunction with FIG. 1. Photodetector 202 is implemented as a pinned photodiode consisting of n+ pinning layer 204 and p-type collection region 206 formed within n-well 208. Well 208 is formed within p-epitaxial layer 210 and extends to the top surface of the silicon.

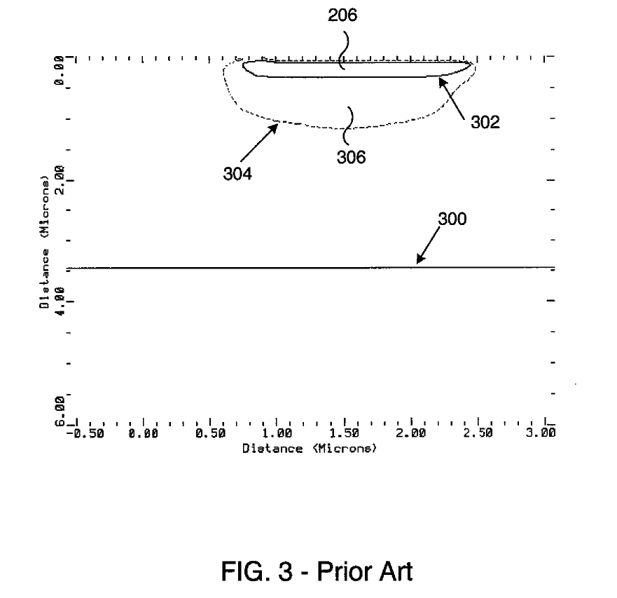

FIG. 3 is a graphical view of exemplary junction and depletion edges for collection region 206 shown in FIG. 2. For simplicity, FIG. 3 does not show the junctions and depletion regions for the other components in pixel 200. Line 300 depicts the junction between well 208 and epitaxial layer 210 (see FIG. 2). Junction 302 represents the junction between collection region 206 and well 208 (see FIG. 2) while boundary 304 defines the depletion region 306 of photodetector 202. Junction 302 has a depth of approximately 0.4 micrometers within well 208 while depletion region 304 has a depth of approximately 1.1 micrometers in the embodiment shown in FIG. 3.

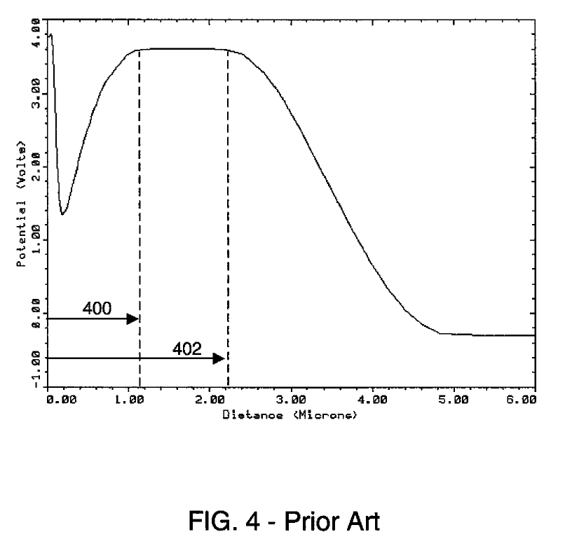

FIG. 4 is an exemplary one-dimensional potential profile of photodetector 202 taken along line B-B′ in FIG. 2. Depletion depth defines the collecting boundary of a photodetector and sink depth is the depth past which charge carriers are drained into the substrate. Photodetector 202 has a depletion depth 400 of approximately 1.1 micrometers and a sink depth 402 of approximately 2.2 micrometers.

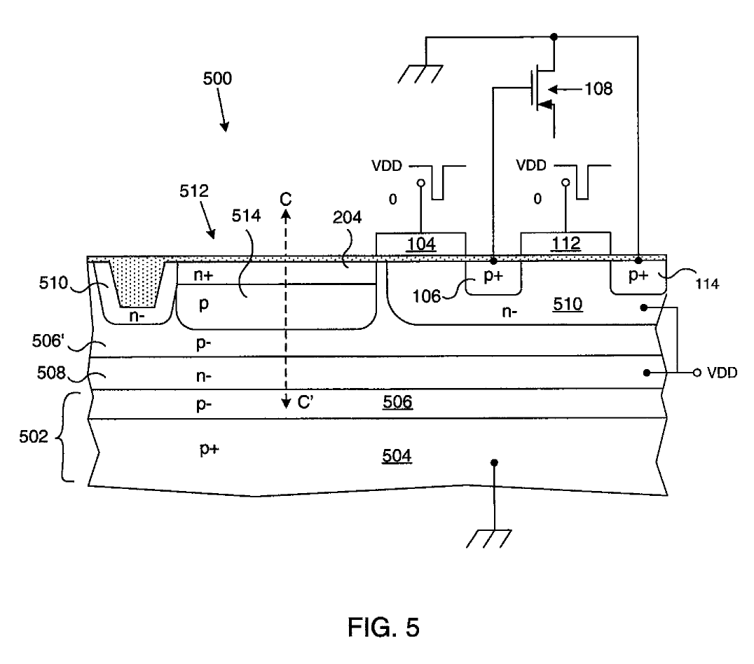

Referring now to FIG. 5, there is shown a cross-sectional schematic view along line A-A′ in FIG. 1 illustrating a first pixel structure in an embodiment in accordance with the invention. Pixel 500 includes transfer gate 104, charge-to-voltage converter 106, source follower transistor 108, and reset gate 112 described in conjunction with FIG. 1. Pixel 500 is implemented as a pMOS Active Pixel Sensor (APS) pixel and charge-to-voltage converter 106 as a floating diffusion in an embodiment in accordance with the invention. APS pixels have one or more electronic components formed within the pixel itself. For example, in FIG. 5 source follower transistor 108 is formed within pixel 500.

The term “substrate layer” is defined herein to include both a substrate having one or more epitaxial layers formed thereon as well as a bulk substrate that does not have any epitaxial layers formed thereon. In the embodiment shown in FIG. 5, substrate layer 502 includes p++ substrate 504 and p-epitaxial layer 506. Buried n-layer 508 is formed within a portion of p-epitaxial layer 506. An n-well 510 is formed within a portion of p-epitaxial layer 506 and is disposed laterally adjacent to photodetector 512. Photodetector 512 is implemented as a pinned photodiode consisting of n+ pinning layer 204 and p-type collection region 514 formed within p-epitaxial layer 508. An undoped region 506′ of p-epitaxial layer 506 is positioned between collection region 514 and buried n-layer 508. Region 506′ is called “undoped” because the region is not doped with any of the dopants used to form buried layer 508, well 510, and collection region 514. The doping of undoped region 506′ is substantially the same as epitaxial layer 506. Undoped region 506′ effectively produces an “extension” of p-type collection region 514 in photodetector 512. This results in a deeper depletion depth and a deeper junction depth for photodetector 512.

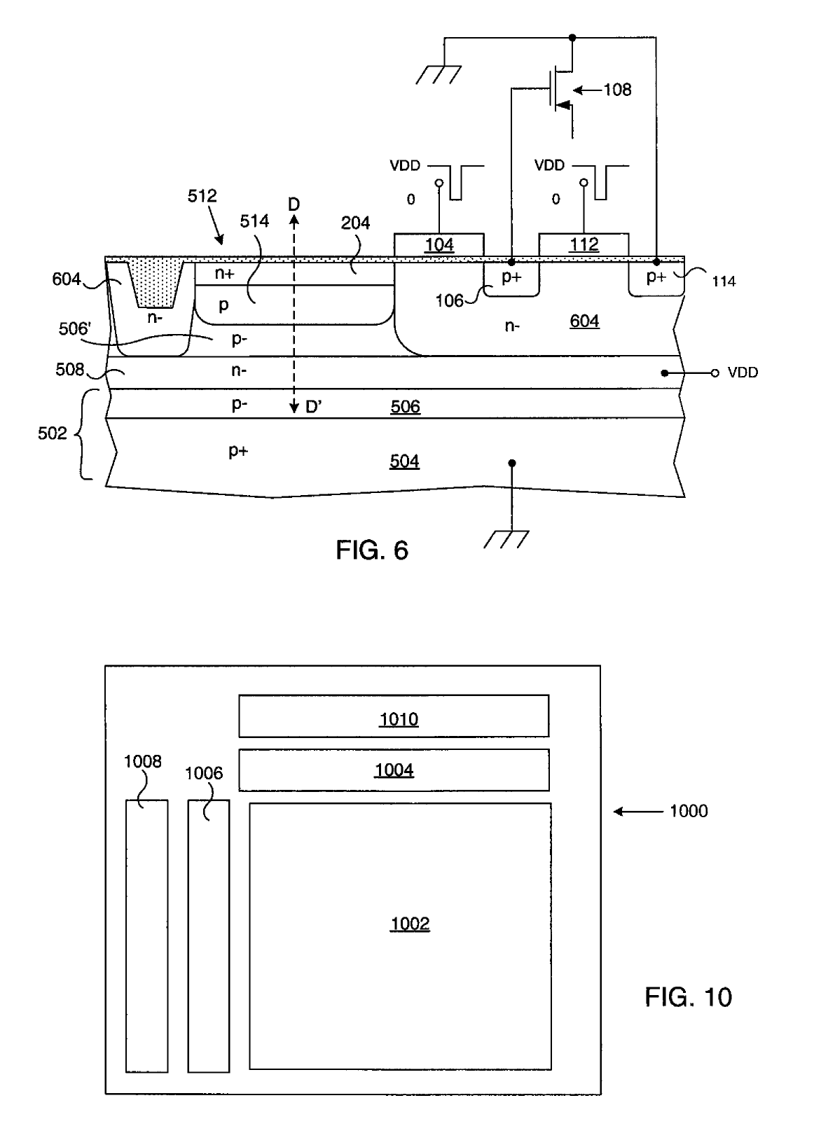

FIG. 6 is a cross sectional view along line A-A′ in FIG. 1 depicting a second pixel structure in an embodiment in accordance with the invention. Pixel 600 is identical to pixel 500 in FIG. 5 except for well 602. Well 604 is formed within portions of p-epitaxial layer 506 such that at its deepest depth well 604 abuts buried layer 508. As with the embodiment shown in FIG. 5, undoped region 506′ effectively produces an “extension” of collection region 514 in photodetector 512. This extension produces a deeper depletion depth and a deeper junction depth for photodetector 512.

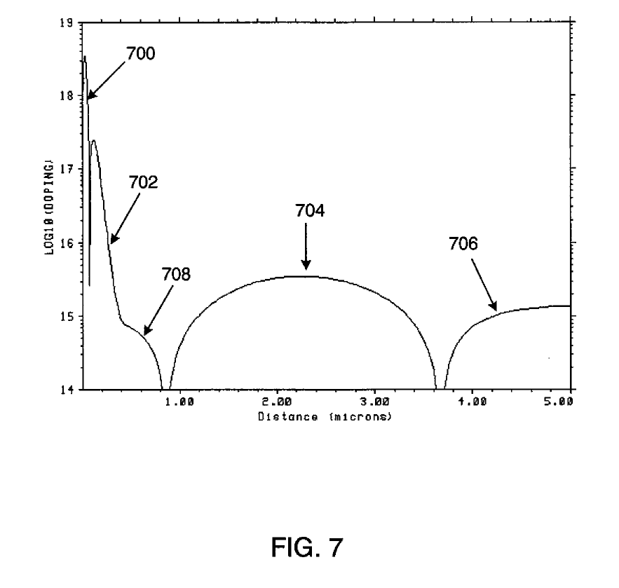

Referring now to FIG. 7, there is shown an exemplary one-dimensional doping profile of photodetector 512 taken along line C-C′ in FIG. 5 and along line D-D′ in FIG. 6. Profile 700 depicts the doping profile of pinning layer 204, profile 702 the doping profile of collection region 514, profile 704 the doping profile of buried n-layer 508, and profile 706 the doping profile of p-epitaxial layer 506. Note that profile 702 includes an extended “tail” region 708 for the doping profile of collection region 514. The extended tail region 708 results in the deeper photodetector junction depth.

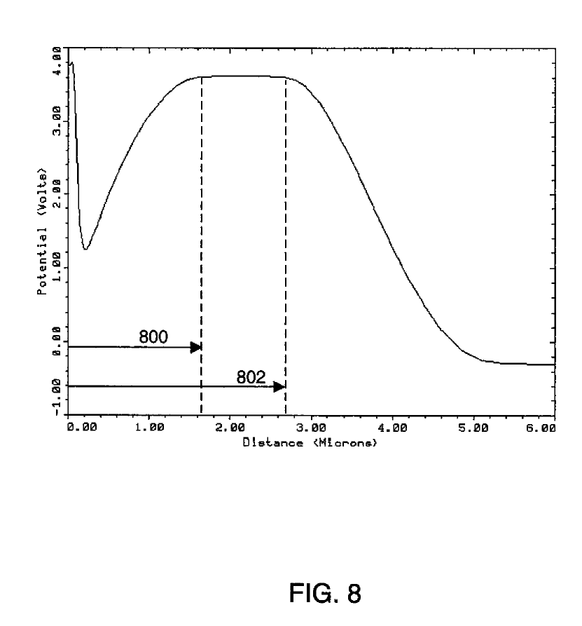

FIG. 8 is an exemplary one-dimensional potential profile of photodetector 512 taken along line C-C′ in FIG. 5 and along line D-D′ in FIG. 6. Photodetector 512 has a depletion depth 800 of approximately 1.7 micrometers and a sink depth 802 of approximately 2.7 micrometers. In comparison, as shown in FIG. 4, prior art photodetector 202 had a depletion depth (see 400 in FIG. 4) of approximately 1.1 micrometers and a sink depth (see 402 in FIG. 4) of approximately 2.2 micrometers. The pixel structures shown in FIGS. 5 and 6 each have an increase in quantum efficiency compared to that of the prior art pixel structure shown in FIG. 2.

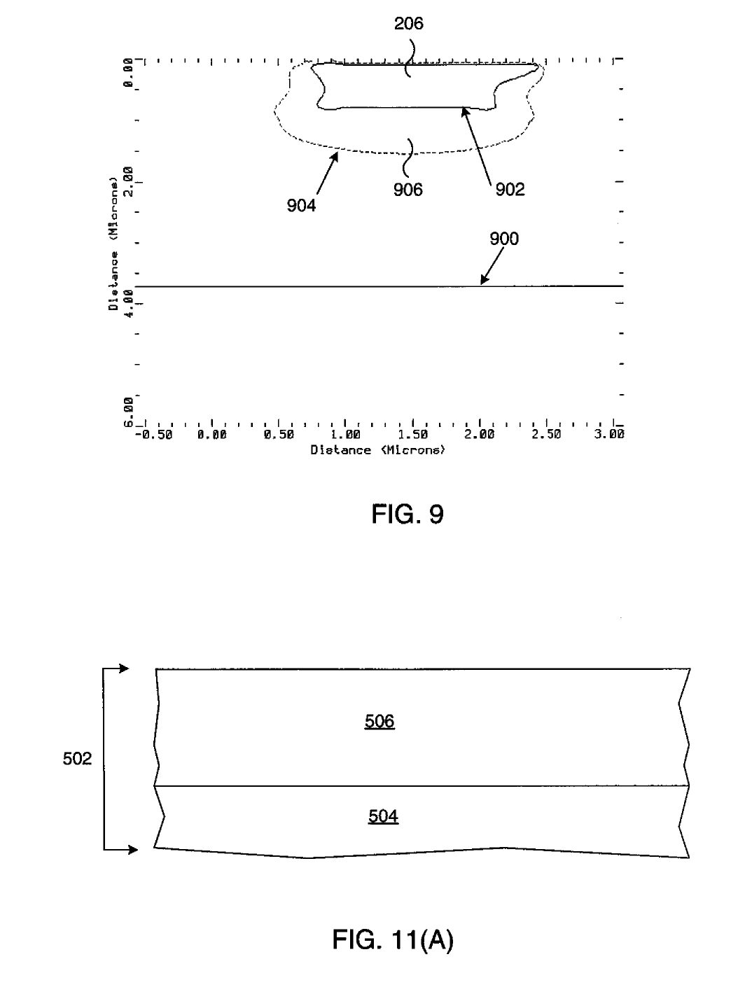

Referring now to FIG. 9, there is shown an exemplary two-dimensional cross-sectional view showing the junctions and depletion boundaries of collection region 514 in FIG. 5. For simplicity, FIG. 9 does not show the junctions and depletion regions for the other components in pixel 500. Line 900 depicts the junction between the bottom of buried layer 508 and p-epitaxial layer 506. Junction 902 represents the junction of the collection region 514 while boundary 904 illustrates the depletion region 906 of photodetector 512. Comparing FIG. 9 to FIG. 3, junction 904 is deeper than junction 304 and depletion region 906 is larger than depletion region 306. The doping profiles of FIG. 7, the potential profiles of FIG. 8, and the junctions and depletion boundaries of FIG. 9 are included for one embodiment in accordance with the invention. Those skilled in the art will appreciate that the doping profiles, potential profiles, junctions, and depletion boundaries shown in FIGS. 7-9 are examples and that their actual shapes and values can vary in other embodiments in accordance with the invention.

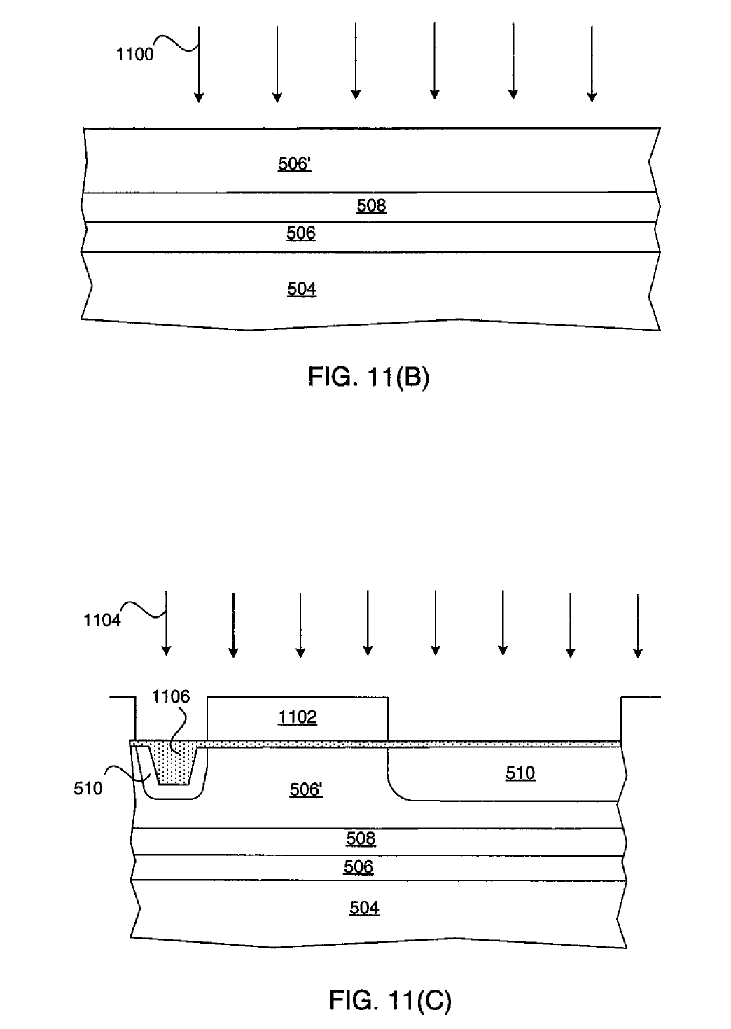

FIG. 10 is a block diagram of a top view of an image sensor in an embodiment in accordance with the invention. Image sensor 1000 includes imaging area 1002, column decoder 1004, row decoder 1006, digital logic 1008, and analog or digital output circuits 1010. Imaging area 1002 includes an array of pixels having the pixel structure of FIG. 5 or FIG. 9. Image sensor 1000 is implemented as a Complementary Metal Oxide Semiconductor (CMOS) image sensor in an embodiment in accordance with the invention. Thus, column decoder 1004, row decoder 1006, digital logic 1008, and analog or digital output circuits 1010 are implemented as standard CMOS electronic circuits that are operatively connected to imaging area 1002. Those skilled in the art will recognize that other peripheral circuitry configurations or architectures can be implemented in other embodiments in accordance with the invention.

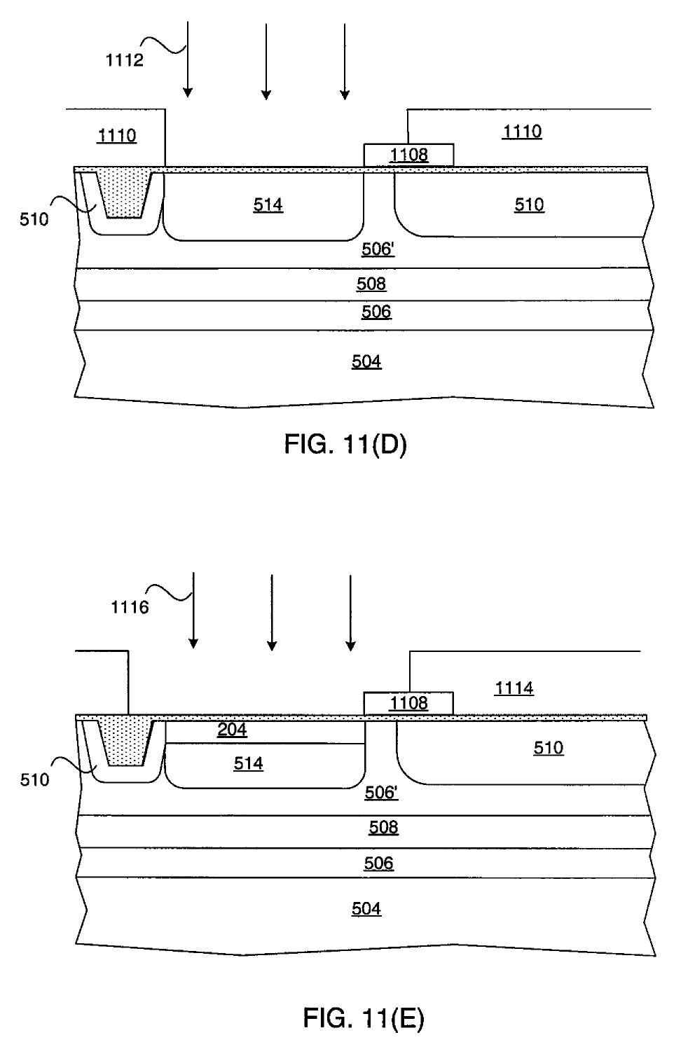

Referring now to FIGS. 11(A)-11(E), there is shown cross-sectional views of a portion of a pixel that are used to illustrate a method of fabricating buried layer 508, well 510, and photodetector 512 in an embodiment in accordance with the invention. Only those fabrication steps necessary to understanding the present invention are shown in FIG. 11. Initially epitaxial layer 506 is formed on a substrate 504 using a known fabrication technique (see FIG. 11(A)). Epitaxial layer 506 and substrate 504 are doped with a dopant of a first conductivity type and collectively form substrate layer 502.

Next, as shown in FIG. 11(B), a portion of epitaxial layer 506 is doped with dopants of a second conductivity type (doping represented by arrows 1100) to form buried layer 508. Buried layer 508 can be formed using any known conventional fabrication technique, such as, for example, ion implantation. As can be seen in FIG. 11(B), buried layer 508 divides epitaxial layer 506 into two regions (506, 506′) having substantially the same amount of doping. The undoped region 506′ that is shown in FIGS. 5 and 6 and produces an “extension” of the collection region of a photodetector will be formed from a portion of epitaxial layer region 506′ in the embodiment shown in FIG. 11.

Next, as shown in FIG. 11(C), mask 1102 is deposited and patterned over the pixel and wells 510 are formed in portions of epitaxial layer region 506′ by doping the portions of epitaxial layer region 506′ with a dopant of the second conductivity type (doping represented by arrows 1104 in FIG. 11(C)). Those skilled in the art will appreciate that shallow trench isolation (STI) 1106 is formed in epitaxial layer region 506′ and filled with a dielectric material prior to the formation of wells 510 (formation of STI 1106 is optional and not part of the present invention). In the embodiment shown in FIG. 11(C), wells 510 do not abut buried layer 508. Wells 510 abut buried layer 508 in other embodiments in accordance with the invention.

Mask 1102 is then removed and transfer gate 1108 formed on the surface of the pixel, as shown in FIG. 11(D). Mask 1110 is deposited and patterned over the pixel and collection region 514 is formed in a portion of epitaxial layer region 506′ by doping a portion of epitaxial layer 506′ with a dopant of the first conductivity type (doping represented by arrows 1112). Mask 1110 does not cover all of gate 1108 because the dopants of the first conductivity type are implanted into collection region 514 self-aligned to transfer gate 1108.

Mask 1110 is then removed and another mask 1114 is deposited and patterned on the surface of the pixel. Pinning layer 204 is then formed on collection region 514 by doping a portion of collection region 514 with a dopant of the second conductivity type (doping represented by arrows 1116). Pinning layer 204 and collection region 514 collectively form a pinned photodetector. Although FIG. 11(E) depicts the one well 510 that is formed adjacent gate 1108 as not abutting collection region 514 and pinning layer 204, those skilled in the art will appreciate that the well can be formed to abut the photodetector. Thus, as shown in FIG. 11(A), buried layer 508, wells 510, and collection region 514 are formed in epitaxial layer region 506′ such that a region 506′ having substantially the same amount of doping as epitaxial layer 506 resides between collection region 514 of the pinned photodetector and buried layer 508.

In another embodiment in accordance with the invention, substrate layer 502 is formed only by substrate 504. Buried layer 508 then divides substrate 504 into two regions having substantially the same amount of doping. Buried layer 508, wells 510, and collection region 514 are fabricated so that undoped region 506′ of FIG. 5 and 6 is formed from a portion of substrate 504. In this embodiment, the doping of undoped region 506′ is substantially the same as the doping of substrate 504.

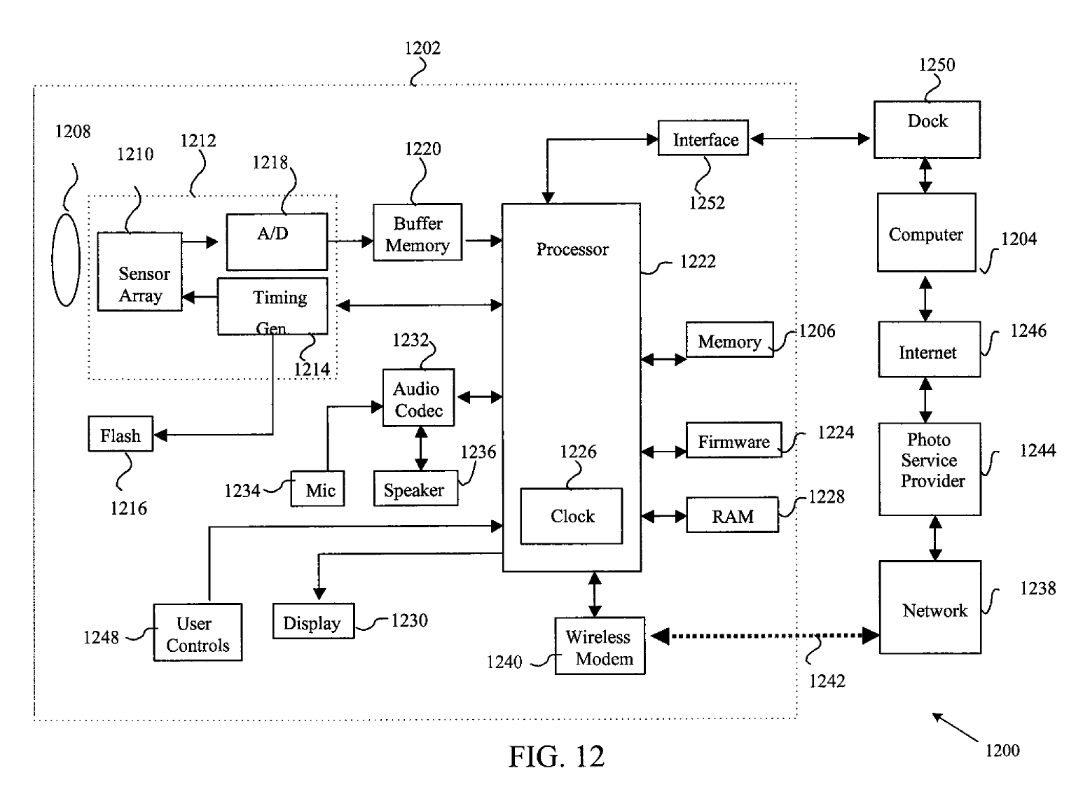

FIG. 12 is a block diagram of an imaging system that can be used with an image sensor that incorporates the pixel structure with photodetectors having extended depletion depths in an embodiment in accordance with the invention. Imaging system 1200 includes digital camera phone 1202 and computing device 1204. Digital camera phone 1202 is an example of an image capture device that can use an image sensor incorporating the present invention. Other types of image capture devices can also be used with the present invention, such as, for example, digital still cameras and digital video camcorders.

Digital camera phone 1202 is a portable, handheld, battery-operated device in an embodiment in accordance with the invention. Digital camera phone 1202 produces digital images that are stored in memory 1206, which can be, for example, an internal Flash EPROM memory or a removable memory card. Other types of digital image storage media, such as magnetic hard drives, magnetic tape, or optical disks, can alternatively be used to implement memory 1206.

Digital camera phone 1202 uses lens 1208 to focus light from a scene (not shown) onto image sensor array 1210 of active pixel sensor 1212. Image sensor array 1210 provides color image information using the Bayer color filter pattern in an embodiment in accordance with the invention. Image sensor array 1210 is controlled by timing generator 1214, which also controls flash 1216 in order to illuminate the scene when the ambient illumination is low.

The analog output signals output from the image sensor array 1210 are amplified and converted to digital data by analog-to-digital (A/D) converter circuit 1218. The digital data are stored in buffer memory 1220 and subsequently processed by digital processor 1222. Digital processor 1222 is controlled by the firmware stored in firmware memory 1224, which can be flash EPROM memory. Digital processor 1222 includes real-time clock 1226, which keeps the date and time even when digital camera phone 1202 and digital processor 1222 are in a low power state. The processed digital image files are stored in memory 1206. Memory 1206 can also store other types of data, such as, for example, music files (e.g. MP3 files), ring tones, phone numbers, calendars, and to-do lists.

In one embodiment in accordance with the invention, digital camera phone 1202 captures still images. Digital processor 1222 performs color interpolation followed by color and tone correction, in order to produce rendered sRGB image data. The rendered sRGB image data are then compressed and stored as an image file in memory 1206. By way of example only, the image data can be compressed pursuant to the JPEG format, which uses the known “Exif” image format. This format includes an Exif application segment that stores particular image metadata using various TIFF tags. Separate TIFF tags can be used, for example, to store the date and time the picture was captured, the lens f/number and other camera settings, and to store image captions.

Digital processor 1222 produces different image sizes that are selected by the user in an embodiment in accordance with the invention. One such size is the low-resolution “thumbnail” size image. Generating thumbnail-size images is described in commonly assigned U.S. Pat. No. 5,164,831, entitled “Electronic Still Camera Providing Multi-Format Storage Of Full And Reduced Resolution Images” to Kuchta, et al. The thumbnail image is stored in RAM memory 1228 and supplied to display 1230, which can be, for example, an active matrix LCD or organic light emitting diode (OLED). Generating thumbnail size images allows the captured images to be reviewed quickly on color display 1230.

In another embodiment in accordance with the invention, digital camera phone 1202 also produces and stores video clips. A video clip is produced by summing multiple pixels of image sensor array 1210 together (e.g. summing pixels of the same color within each 4 column×4 row area of the image sensor array 1210) to create a lower resolution video image frame. The video image frames are read from image sensor array 1210 at regular intervals, for example, using a 15 frame per second readout rate.

Audio codec 1232 is connected to digital processor 1220 and receives an audio signal from microphone (Mic) 1234. Audio codec 1232 also provides an audio signal to speaker 1236. These components are used both for telephone conversations and to record and playback an audio track, along with a video sequence or still image.

Speaker 1236 is also used to inform the user of an incoming phone call in an embodiment in accordance with the invention. This can be done using a standard ring tone stored in firmware memory 1224, or by using a custom ring-tone downloaded from mobile phone network 1238 and stored in memory 1206. In addition, a vibration device (not shown) can be used to provide a silent (e.g. non-audible) notification of an incoming phone call.

Digital processor 1222 is connected to wireless modem 1240, which enables digital camera phone 1202 to transmit and receive information via radio frequency (RF) channel 1242. Wireless modem 1240 communicates with mobile phone network 1238 using another RF link (not shown), such as a 3GSM network. Mobile phone network 1238 communicates with photo service provider 1244, which stores digital images uploaded from digital camera phone 1202. Other devices, including computing device 1204, access these images via the Internet 1246. Mobile phone network 1238 also connects to a standard telephone network (not shown) in order to provide normal telephone service in an embodiment in accordance with the invention.

A graphical user interface (not shown) is displayed on display 1230 and controlled by user controls 1248. User controls 1248 include dedicated push buttons (e.g. a telephone keypad) to dial a phone number, a control to set the mode (e.g. “phone” mode, “calendar” mode” “camera” mode), a joystick controller that includes 4-way control (up, down, left, right) and a push-button center “OK” or “select” switch, in embodiments in accordance with the invention.

Dock 1250 recharges the batteries (not shown) in digital camera phone 1202. Dock 1250 connects digital camera phone 1202 to computing device 1204 via dock interface 1252. Dock interface 1252 is implemented as wired interface, such as a USB interface, in an embodiment in accordance with the invention. Alternatively, in other embodiments in accordance with the invention, dock interface 1252 is implemented as a wireless interface, such as a Bluetooth or an IEEE 802.11b wireless interface. Dock interface 1252 is used to download images from memory 1206 to computing device 1204. Dock interface 1252 is also used to transfer calendar information from computing device 1204 to memory 1206 in digital camera phone 1202.

The invention has been described with reference to specific embodiments of the invention. However, it will be appreciated that a person of ordinary skill in the art can effect variations and modifications without departing from the scope of the invention. For example, pixel 500 or pixel 600 can be implemented as an nMOS pixel with the dopant types reversed. Pixel configurations can include additional, fewer, or different components than the ones shown in FIGS. 5 and 6. An image sensor can be implemented as a CMOS or charge-coupled device (CCD) image sensor. And substrate 502 can be implemented as a bulk wafer without an epitaxial layer.

Additionally, photodetector 512 can be implemented using alternate structures or conductivity types in other embodiments in accordance with the invention. Photodetector 512 can be implemented as an unpinned p-type diode formed in an n-well in a p-type epitaxial layer or substrate in another embodiment in accordance with the invention. In other embodiments in accordance with the invention, photodetector 512 can include a pinned or unpinned n-type diode formed within a p-well in an n-type substrate. And finally, although a simple non-shared pixel structure is shown in FIG. 5 and FIG. 6, a shared architecture is used in another embodiment in accordance with the invention. One example of a shared architecture is disclosed in U.S. Pat. No. 6,107,655.

### PARTS LIST:

100 photodetector
102 pixel
104 transfer gate
106 floating diffusion
108 source follower transistor
110 row select transistor
112 reset transistor
114 power supply (VDD)
200 pixel
202 photodetector
204 pinning layer
206 collection region
208 well
210 epitaxial layer
300 junction
302 junction
304 depletion region
306 depletion region boundary
400 depletion depth
402 sink depth
500 pixel
502 substrate
504 substrate
506 epitaxial layer
506′ region of epitaxial layer
508 buried layer
510 well
512 photodetector
514 collection region
600 pixel structure
602 well
700 doping profile of pinning layer
702 doping profile of collection region
704 doping profile of well
706 doping profile of epitaxial layer
708 extended tail of doping profile of collection region
800 depletion depth
802 sink depth
900 junction
902 junction
904 depletion region
906 depeletion region boundary
1000 image sensor
1002 imaging area
1004 column decoder
1006 row decoder
1008 digital logic
1010 output circuits
1100 arrows representing doping with dopant of a second conductivity type
1102 mask
1104 arrows representing doping with dopant of a second conductivity type
1108 shallow trench isolation
1108 gate
1110 mask
1112 arrows representing doping with dopant of a first conductivity type
1114 mask
1116 arrows representing doping with dopant of a second conductivity type
1200 imaging system
1202 camera phone
1204 computing device
1206 memory
1208 lens
1210 image sensor array
1212 active pixel sensor
1214 timing generator
1216 flash
1218 analog-to-digital converter
1220 buffer memory
1222 digital processor
1224 firmware memory
1226 clock
1228 RAM memory
1230 display
1232 audio codec
1234 microphone
1236 speaker
1238 mobile phone network
1240 wireless modem
1242 RF channel
1244 photo service provider
1246 internet
1248 user controls
1250 dock
1252 dock interface

1. An image sensor comprising:
an imaging area that includes a plurality of pixels each having a collection region doped with a dopant of a first conductivity type;
a substrate layer of the first conductivity type;
a buried layer spanning the imaging area and disposed in a portion of the substrate layer, wherein the buried layer is doped with a dopant of a second conductivity type; and
a plurality of wells disposed in portions of the substrate layer with each well positioned laterally adjacent to each collection region in each pixel, wherein each well is doped with another dopant of the second conductivity type, and wherein the buried layer and each collection region are formed such that a region of the substrate layer having substantially the same doping as the substrate layer resides between each collection region and the buried layer.

2. The image sensor of claim 1, further comprising one or more electronic components disposed in each pixel.

3. The image sensor of claim 1, further comprising one or more electronic components disposed in the substrate layer outside of the imaging area and electrically connected to the imaging area.

4. The image sensor of claim 1, wherein each well is disposed in a portion of the substrate layer such that each well abuts the buried layer.

5. The image sensor of claim 1, further comprising a pinning layer formed over each collection region to form a pinned photodiode.

6. The image sensor of claim 1, wherein the substrate layer comprises a substrate with an epitaxial layer formed thereon, and wherein the buried layer, the plurality of wells, and the collection regions are formed in portions of the epitaxial layer.

7. The image sensor of claim 1, wherein the substrate layer comprises a substrate, and wherein the buried layer, the plurality of wells, and the collection regions are formed in portions of the substrate.

8. The image sensor of claim 1, wherein the first conductivity type is p type and the second conductivity type is n type.

9. An image capture device comprising:
an image sensor comprising:
an imaging area that includes a plurality of pixels each having a collection region doped with a dopant of a first conductivity type;
a substrate layer of the first conductivity type;
a buried layer spanning the imaging area and disposed in a portion of the substrate layer, wherein the buried layer is doped with a dopant of a second conductivity type;
a plurality of wells disposed in portions of the substrate layer with each well positioned laterally adjacent to each collection region in each pixel, wherein each well is doped with another dopant of the second conductivity type, and wherein the buried layer and each collection region are formed such that a region of the substrate layer having substantially the same doping as the substrate layer resides between the buried layer and each collection region.

10. The image capture device of claim 9, wherein the image sensor further comprises one or more electronic components disposed in each pixel.

11. The image capture device of claim 9, further comprising one or more electronic components disposed in the substrate layer outside of the imaging area and electrically connected to the imaging area.

12. The image capture device of claim 9, wherein the first conductivity type is p type and the second conductivity type is n type.

13. The image capture device of claim 9, further comprising a pinning layer formed over each collection region to form a pinned photodiode.

14. The image capture device of claim 9, wherein the substrate layer comprises a substrate with an epitaxial layer formed thereon, and wherein the buried layer, the plurality of wells, and the collection regions are formed in portions of the epitaxial layer.

15. The image capture device of claim 9, wherein the substrate layer comprises a substrate, and wherein the buried layer, the plurality of wells, and the collection regions are formed in portions of the substrate.
